(19) United States
(12) Patent Application Publication
(10) Pub. No.: US 2007/0287244 A1
(43) Pub. Date: Dec. 13, 2007

(54) ALTERNATIVE INTEGRATION SCHEME FOR CMOS S/D SiGe PROCESS

(75) Inventors: Meihua Shen, Fremont, CA (US); Yonah Cho, Sunnyvale, CA (US); Mark Naoshi Kawaguchi, Mountain View, CA (US); Faran Nouri, Los Altos, CA (US); Diana Xiaobing Ma, Saratoga, CA (US)

Correspondence Address: TOWNSEND AND TOWNSEND AND CREW LLP / AMAT, TWO EMBARCADERO CENTER, EIGHTH FLOOR, SAN FRANCISCO, CA, 94111-3834, US

(73) Assignee: Applied Materials, Inc., A Delaware corporation, Santa Clara, CA (US)

(21) Appl. No.: 11/739,099

(22) Filed: Apr. 24, 2007

Related U.S. Application Data
(60) Provisional application No. 60/795,406, filed on Apr. 26, 2006.

(51) Int. Cl. H01L 21/8236

(52) U.S. Cl. 438/199; 257/E21.598

(57) ABSTRACT

A method for fabricating a semiconductor device with adjacent PMOS and NMOS devices on a substrate includes forming a PMOS gate electrode with a PMOS hardmask on a semiconductor substrate with a PMOS gate dielectric layer in between, forming an NMOS gate electrode with an NMOS hardmask on a semiconductor substrate with an NMOS gate dielectric layer in between, forming an oxide liner over a portion of the PMOS gate electrode and over a portion of the NMOS gate electrode, forming a lightly doped N-Halo implant, depositing a nitride layer over the oxide liner, depositing photoresist on the semiconductor substrate in a pattern that covers the NMOS device, etching the nitride layer from the PMOS device, wherein the etching nitride layer leaves a portion of the nitride layer on the oxide liner, etching semiconductor substrate to form a Si recess, and depositing SiGe into the Si recesses, wherein the SiGe and the nitride layer enclose the oxide liner. The method can also include implanting in the semiconductor substrate a source and drain region for the PMOS.

### CROSS-REFERENCES TO RELATED APPLICATIONS

This application claims the benefit of U.S. Provisional Application No. 60/795,406, filed Apr. 26, 2006, which is incorporated herein by reference in its entirety for all purposes.

### BACKGROUND

Aspects of the present invention relate generally to the field of semiconductor devices and the manufacture of those semiconductor devices. More particularly, embodiments of the present invention relate to methods and apparatuses for providing defect reduction arising from over etching CMOS devices when making silicon recesses used as the source/drain of a CMOS.

As computers become faster and more powerful, the semiconductor devices running those computers are becoming smaller and more complex. Many modern semiconductor devices are made of CMOS (Complimentary Metal-Oxide-Semiconductor) transistors and capacitors, in which the CMOS transistors generally include a source, drain, and gate. The gate is sometimes called a gate stack because it may include several components, such as a gate electrode and an underlying gate dielectric. Sidewall spacers (also called spacers or spacer layers) may be adjacent to the gate structure and usually include an oxide layer and a nitride layer component.

Although CMOS devices are common semiconductor devices found in many computers, they are becoming increasingly more difficult to make. One reason why it is becoming more difficult to make CMOS devices is that these devices are becoming smaller and therefore the tolerance associated with each CMOS device is becoming tighter. One method for fabricating such CMOS devices includes forming a patterned mask (e.g., photoresist mask) on a material layer disposed beneath such a mask (i.e., on an underlying layer) and then etching the material layer using the patterned photoresist mask as an etch mask. The etch mask generally is a replica of the structure to be formed (i.e., etched) in the underlying layer (or layers). As such, the etch mask has the same topographic dimensions as the structures being formed in the underlying layer(s).

Manufacturing variables of an etch process may result in a broad statistical distribution (e.g., large σ, where σ is a standard deviation) for the dimensions of the structures formed within a group (e.g., batch or lot) of wafers being etched. Moreover, variability in the manufacturing process can also cause statistical distributions in structural dimensions within a single wafer.

Conventional integration schemes used to manufacture CMOS devices are susceptible to defects within a wafer resulting from process variations. FIGS. 1A-1D illustrate a conventional integration scheme, which is susceptible to process variations, used to manufacture the SiGe source/drain in a CMOS device.

FIG. 1A illustrates a partially fabricated CMOS 100 having a partially fabricated PMOS device 102 and a partially fabricated NMOS device 104 positioned side-by-side. The PMOS device 102 has a PMOS substrate 110A, a PMOS gate dielectric layer 115A, a PMOS gate electrode 120A, a PMOS oxide layer 125A, a PMOS hardmask 135A, a PMOS spacer layer 140A and a PMOS cap layer 145A. Similarly the NMOS device 104 has an NMOS substrate 110B, an NMOS gate dielectric layer 115B, an NMOS gate electrode 120B, an NMOS oxide layer 125B, an NMOS hardmask 135B, an NMOS spacer layer 140B, an NMOS cap layer 145B, and an NMOS photoresist layer 150.

PMOS substrate 110A and NMOS substrate 110B are silicon substrates. PMOS gate electrode 120A and NMOS gate electrode 120B are made of polysilicon. PMOS oxide layer 125A and NMOS oxide layer 125B are formed along laterally opposite sidewalls of the PMOS gate electrode 120A and the NMOS gate electrode 120B, respectively. The PMOS oxide layer 125A and NMOS oxide layer 125B also extend over portions of the substrate. PMOS hardmask 135A and NMOS hardmask 135B are deposited directly on top of the PMOS gate electrode 120A and the NMOS gate electrode 120B, respectively. Both the PMOS hardmask 135A and the NMOS hardmask 135B are made of silicon oxide. PMOS spacer layer 140A and NMOS spacer layer 140B are deposited over the PMOS oxide layer 125A and the NMOS oxide layer 125B. PMOS cap layer 145A and NMOS cap layer 145B are deposited to cover all of previously mentioned layers and are deposited as one layer over the substrate having the PMOS hardmask 135A and NMOS hardmask 135B already deposited over the electrodes. NMOS photoresist layer 150 is deposited over the NMOS cap layer 145B and is used to protect the NMOS device 104 while the PMOS device 102 is processed.

FIG. 1B shows the partially fabricated CMOS 100 after the cap layer has been opened by an open cap etching processes. In FIG. 1B the partially fabricated NMOS device 104 remains the same after the etching process because it is protected by the photoresist 150. However, since the partially fabricated PMOS device 102 does not have photoresist, the PMOS cap layer 145A is etched off along with some of the PMOS hardmask layer 135A, some of the spacer layer 140A, and some of the PMOS oxide layer 145A. The open cap process leaves behind a small amount of the PMOS cap layer 145A covering the PMOS spacer layer 140A. When using this method of fabricating the CMOS 100 device, care must be taken to prevent removal of too much material from the corner region 165.

FIG. 1C shows the partially fabricated CMOS 100 after the silicon recess has been etched into the substrate using a silicon recess etching process. FIG. 1C shows that when the silicon recesses are etched into the substrate using this process, the PMOS hardmask 135A, the PMOS spacer layer 140A and the PMOS oxide layer 125A are further etched away. If this silicon recess etching process removes too much material from the corner region 165, then the PMOS device will be defective. Specifically, if the PMOS hardmask layer 135A, the PMOS spacer layer 140A and the PMOS oxide layer 125A are etched so that the gate is exposed then problems can arise during the subsequent source/drain deposition process.

FIG. 1D shows the partially fabricated CMOS 100 after stripping away the photoresist layer 150, which was covering the partially fabricated NMOS device 104, cleaning the entire CMOS 100 device, and selectively depositing silicon-germanium (SiGe) into the recesses shown in FIG. 1C to make the source/drain regions 180 of the PMOS 102. The source/drain 180 material, which is SiGe, is deposited by epitaxial (epi) deposition techniques. Selective epi deposition allows the SiGe to deposit only on silicon or silicon containing material such as a silicon substrate. Selective deposition of SiGe on the structure with exposed corner region 165 can lead to unwanted SiGe deposition on region 165. When the corner region 165 has been over etched and the PMOS oxide layer 125A and the PMOS spacer layer 140A are below the PMOS gate electrode 120A. If the corner region 165 has been over etched, then the PMOS gate electrode 120A, which is made of polysilicon, is exposed during the selective SiGe epi deposition process allowing the SiGe to deposit in the corner region 165. Since SiGe in the corner region 165 will make the CMOS device 100 defective, care must be taken to prevent over etching or under etching these devices.

FIG. 2A illustrates a PMOS device that has been properly etched during the steps described above with reference to FIGS. 1A-1D. The properly etched PMOS device shows that SiGe has been deposited only in the Si recess regions during the SiGe epitaxial deposition process, as preferred. FIG. 2B illustrates a PMOS device that has been over etched during the steps described above with reference to FIGS. 1A-1D. The over etched PMOS device shows that SiGe has been deposited in the corner region 165 as well as in the Si recesses during SiGe epitaxial deposition process. Excessive SiGe 185 has deposited onto the corner regions 165 during the deposition process because the previous etch process removed too much of the PMOS spacer layer 140A and the PMOS oxide layer 125A, exposing the PMOS gate electrode to the deposition process. Since the PMOS gate electrode 120A is made of polysilicon and the epitaxial process selectively deposits SiGe only on silicon containing materials, the excessive SiGe deposits onto the corner regions 165. The PMOS device shown in FIG. 2A will function appropriately whereas the PMOS device illustrated in FIG. 2B is defective. The problem with the current process is that it is easy to over etch. The current processes require very tight tolerances and often process variations can cause drifts in the process that cause over etching and reduce yields. Additionally, since there are process variations across a wafer, non-uniform etching can result in reduced yields when PMOS devices on some parts of the wafer are over etched and excessive SiGe 185 has been deposited on the corner regions 165 of those PMOS devices.

Therefore, what is needed is a CMOS device and a method for manufacturing the CMOS device which reduces the sensitivity to over etching during the etch steps of the manufacturing of CMOS devices.

### BRIEF SUMMARY

In one embodiment of the present invention a method for fabricating a semiconductor device with adjacent PMOS and NMOS devices on a substrate includes forming a PMOS gate electrode with a PMOS hardmask on a semiconductor substrate with a PMOS gate dielectric layer in between, forming an NMOS gate electrode with an NMOS hardmask on a semiconductor substrate with an NMOS gate dielectric layer in between, forming an oxide liner over a portion of the PMOS gate electrode and over a portion of the NMOS gate electrode, forming lightly doped drain regions by n-type implants in NMOS and by p-type implants in PMOS, implanting HALOs in some cases, depositing a nitride layer over the oxide liner, depositing photoresist on the semiconductor substrate in a pattern that covers the NMOS device, etching the nitride layer from the PMOS device, wherein the etching nitride layer leaves a portion of the nitride layer on the oxide liner, etching semiconductor substrate to form a Si recess, and depositing SiGe into the Si recesses, wherein the SiGe and the nitride layer enclose the oxide liner. The method can also include implanting in the semiconductor substrate a source and drain region for the PMOS. Additionally, depositing SiGe can further include depositing boron (B) doped SiGe.

In another embodiment of the present invention, the method can further include stripping the photoresist from the NMOS.

In yet another embodiment of the present invention, the method can include cleaning the surface of the semiconductor substrate.

In yet another embodiment of the present invention, the step of forming a nitride spacer layer includes exposing the semiconductor substrate to a process gas including Bis-TertiaryButylAmino-Silane (BTBAS).

In yet another embodiment of the present invention, the SiGe is deposited into the Si recesses using epitaxial deposition.

In yet another embodiment of the present invention, the oxide liner is formed along laterally opposite sidewalls of the PMOS gate electrode.

In yet another embodiment of the present invention, the oxide liner is formed along laterally opposite sidewalls of the NMOS gate electrode.

In yet another embodiment of the present invention, the oxide liner is formed along laterally opposite sidewalls of the PMOS gate electrode and extends above the PMOS gate electrode and contacts the PMOS hardmask.

In yet another embodiment of the present invention, the step of etching semiconductor substrate to form a Si recess reduces the height of the oxide liner so that the final height of the oxide liner extends above the height of the PMOS gate electrode.

In yet another embodiment of the present invention, the PMOS hardmask layer is deposited directly over the PMOS gate electrode.

In yet another embodiment of the present invention, the NMOS hardmask layer is deposited directly over the NMOS gate electrode.

In yet another embodiment of the present invention, the method for fabricating a semiconductor device with adjacent PMOS and NMOS devices on a substrate further includes stripping the photoresist from the NMOS, depositing photoresist on the semiconductor substrate in a pattern that covers the PMOS device after the SiGe has been deposited into the Si recess, etching the nitride layer from the NMOS device, wherein the etching nitride layer leaves a portion of the nitride layer on the NMOS oxide liner. This method can further include etching the semiconductor substrate to form a NMOS Si recess, and depositing Si:C into the NMOS Si recesses, wherein the Si:C and the nitride layer enclose the NMOS oxide liner.

In yet another embodiment of the present invention, the method further includes etching the semiconductor substrate to form an NMOS Si recess, and depositing epitaxial silicon carbon (written as “Si:C”, and also known as carbon doped silicon) into the NMOS Si recesses, wherein the Si:C and the nitride layer enclose the NMOS oxide liner.

In yet another embodiment of the present invention, the NMOS oxide liner is formed along laterally opposite sidewalls of the NMOS gate electrode and extends above the NMOS gate electrode and contacts the NMOS hardmask.

In yet another embodiment of the present invention, the step of etching a semiconductor substrate to form a Si recess reduces the height of the NMOS oxide liner less than the amount the NMOS oxide liner extends above the NMOS gate electrode.

In yet another embodiment of the present invention, the method further includes stripping the photoresist from the PMOS.

In another embodiment of the present invention, a method for fabricating a semiconductor device with adjacent PMOS and NMOS devices on a substrate includes forming a nitride layer over a partially fabricated PMOS device and a partially fabricated NMOS device, depositing photoresist on the semiconductor substrate in a pattern that covers the partially fabricated NMOS device, etching through the nitride layer to form Si recesses in the substrate, wherein a portion of the nitride layer remains on the partially fabricated PMOS device, depositing SiGe into the Si recesses, wherein the SiGe and the nitride layer enclose a PMOS gate electrode located in the partially fabricated PMOS device. The step of forming a nitride space layer can include exposing the semiconductor substrate to a process gas including Bis-TertiaryButylAmino-Silane (BTBAS).

In another embodiment of the present invention, the method can further include stripping the photoresist from the partially fabricated NMOS device, depositing photoresist on the semiconductor substrate in a pattern that covers the PMOS device after the SiGe has been deposited into the Si recess, etching through the nitride layer to form Si recesses in the substrate, wherein a portion of the nitride layer remains on the partially fabricated NMOS device, depositing Si:C into the Si recesses, wherein the Si:C and the nitride layer enclose a NMOS gate electrode located in the partially fabricated NMOS device.

In another embodiment of the present invention, a semiconductor device includes a substrate having regions filled with an additive that forms a source/drain for a MOS device, a gate dielectric layer deposited over the substrate, the gate dielectric layer electrically isolates the substrate from subsequently deposited layers, a gate electrode deposited over the gate dielectric layer, an oxide liner formed along laterally opposite sidewalls of the gate electrode, a nitride layer formed along the oxide liner extending above the gate electrode, and wherein the additive and the nitride layer enclose the gate electrode.

In yet another embodiment of the present invention, the regions filled with an additive is a recessed region filled with SiGe.

In yet another embodiment of the present invention, the additive is SiC.

In yet another embodiment of the present invention, the MOS device can be a PMOS device or an NMOS device.

In yet another embodiment of the present invention, the additive used as a source/drain is in direct contact with the nitride layer and encloses the gate electrode.

In yet another embodiment of the present invention, the oxide liner is formed along laterally opposite sidewalls of the gate electrode and extends above the gate electrode.

In yet another embodiment of the present invention, the gate dielectric layer is deposited directly over the substrate.

In yet another embodiment of the present invention, the gate electrode is deposited directed over the gate dielectric layer.

In yet another embodiment of the present invention, the oxide liner is in direct contact with the gate electrode.

In yet another embodiment of the present invention, the nitride layer is in direct contact with the oxide liner.

In yet another embodiment of the present invention, the semiconductor device further includes a hardmask layer deposited over the gate electrode. The hardmask layer can be in direct contact with the gate electrode.

In another embodiment of the present invention, a semiconductor device includes a substrate having regions filled with an additive that forms a source/drain, the additive extends above all surfaces of the substrate, a gate dielectric layer deposited over the substrate, a gate electrode deposited over the gate dielectric layer, an oxide liner formed along laterally opposite sidewalls of the gate electrode, a nitride layer formed along the oxide liner, and wherein the additive and the nitride layer are in direct contact with each other and enclose the gate electrode. The regions filled with an additive can be a recessed region filled with SiGe. Alternatively, the additive can be SiC. The oxide liner can be in direct contact with the gate electrode. The nitride layer can be in direct contact with the oxide liner. The nitride layer can be in direct contact with the oxide liner. The nitride layer can extend above the gate electrode.

In another embodiment of the present invention, a semiconductor device includes both a PMOS device and NMOS device. The PMOS device can include a substrate having a PMOS recessed regions filled with SiGe that forms a source/drain for the PMOS device, a PMOS gate dielectric layer deposited over a portion of the substrate, a PMOS gate electrode deposited over the PMOS gate dielectric layer, a PMOS oxide liner formed along laterally opposite sidewalls of the PMOS gate electrode, a PMOS nitride layer formed along the PMOS oxide liner extending above the PMOS gate electrode, and wherein the SiGe deposited into the PMOS recessed regions and the PMOS nitride layer enclose the PMOS gate electrode. The NMOS device can include a substrate having an NMOS region filled with SiC that forms a source/drain for the NMOS device, an NMOS gate dielectric layer deposited over a portion of the substrate, an NMOS gate electrode deposited over the NMOS gate dielectric layer, an NMOS oxide liner formed along laterally opposite sidewalls of the NMOS gate electrode, an NMOS nitride layer formed along the NMOS oxide liner extending above the NMOS gate electrode, and wherein the SiC deposited into the NMOS region and the NMOS nitride layer enclose the NMOS gate electrode. The PMOS and NMOS devices are adjacent. The PMOS hardmask layer can be directly over the PMOS gate electrode. The NMOS hardmask layer can be directly over the NMOS gate electrode.

In yet another embodiment of the present invention, the SiGe deposited in the PMOS recessed regions extends above the surface of the substrate.

In yet another embodiment of the present invention, the SiC deposited in the NMOS region extends above the surface of the substrate.

In yet another embodiment of the present invention, the NMOS region where the SiC is deposited is a recessed region.

In yet another embodiment of the present invention, the Si:C is deposited in the source/drain region of NMOS without recess etch

In yet another embodiment of the present invention, the SiC deposited into the NMOS recessed regions and the NMOS nitride layer are in direct contact with each other.

In yet another embodiment of the present invention, the SiGe deposited into the PMOS recessed regions and the PMOS nitride layer are in direct contact with each other.

### BRIEF DESCRIPTION OF THE DRAWINGS

FIGS. 1A-1D show a prior art integration scheme for using silicon germanium as a source/drain in a CMOS device.

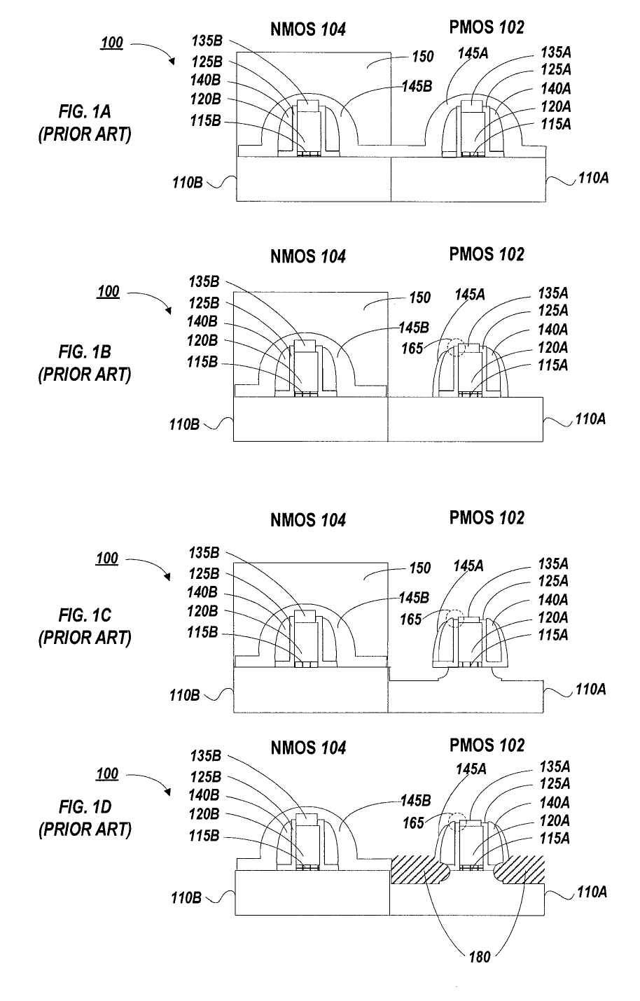

FIG. 2A illustrates a PMOS device that has been properly etched using the integration scheme illustrated in FIGS. 1A-1D.

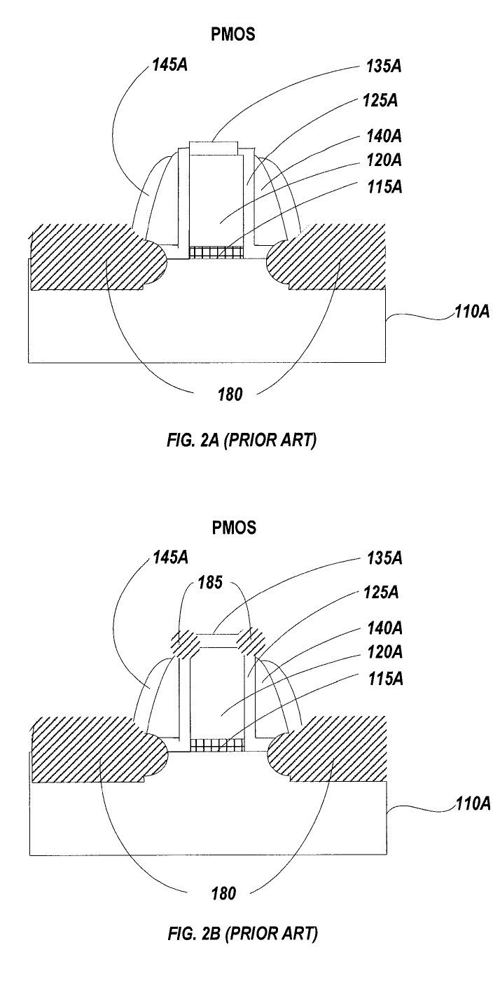

FIG. 2B illustrates a PMOS device that has been over etched using the integration scheme illustrated in FIGS. 1A-1D.

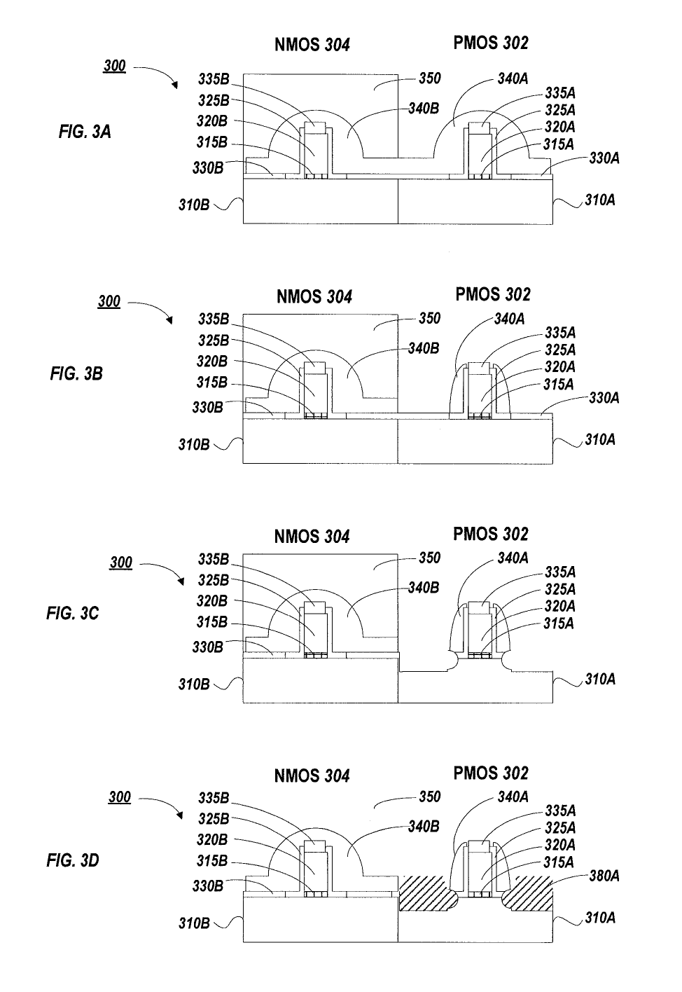

FIGS. 3A-3G illustrate an integration scheme for using silicon germanium as a source/drain in a CMOS device, in accordance with one embodiment of the invention.

FIG. 4 illustrates a PMOS device having a nitride layer in contact with a SiGe source drain in accordance with one embodiment of the invention.

FIG. 5 is a flow chart showing an exemplary method used to manufacture a CMOS device using silicon-germanium as a source/drain material without using a cap layer, in accordance with one embodiment of the invention.

FIG. 6 is a flow chart showing another exemplary method used to manufacture a CMOS device using silicon-germanium as a source/drain material without using a cap layer, in accordance with another embodiment of the invention.

### DETAILED DESCRIPTION

Embodiments of the present invention include a CMOS device that is fabricated without using a cap layer and a manufacturing process for making the CMOS device that is not very sensitive to over etching during the etch steps of the manufacturing process. In some embodiments the CMOS includes a PMOS device and an NMOS device. The PMOS device can further include a substrate having a PMOS recessed region filled with SiGe that forms a source/drain for the NMOS device, a PMOS gate dielectric layer deposited over a portion of the substrate, a PMOS gate electrode deposited over the PMOS gate dielectric layer, a PMOS oxide liner formed along laterally opposite sidewalls of the PMOS gate electrode, a PMOS nitride layer formed along the PMOS oxide liner extending above the PMOS gate electrode, and wherein the SiGe deposited into the PMOS recessed regions and the PMOS nitride layer enclose the PMOS gate electrode. The NMOS device further includes a substrate having an NMOS recessed region filled with Si:C that forms a source/drain for the NMOS device, an NMOS gate dielectric layer deposited over a portion of the substrate, an NMOS gate electrode deposited over the NMOS gate dielectric layer, an NMOS oxide liner formed along laterally opposite sidewalls of the NMOS gate electrode, an NMOS nitride layer formed along the NMOS oxide liner extending above the NMOS gate electrode, and wherein the Si:C deposited into the NMOS recessed regions and the NMOS nitride layer enclose the NMOS gate electrode. In one embodiment, the PMOS and NMOS devices are adjacent. Throughout the specification and claims additive is defined to mean SiGe, Si:C, boron doped SeGe, or phosphorous doped Si:C, in the source and drain region.

One exemplary method of fabricating the CMOS device with adjacent PMOS and NMOS devices on a substrate includes depositing a PMOS gate electrode on a semiconductor substrate with a PMOS gate dielectric layer in between, and depositing an NMOS gate electrode on a semiconductor substrate with an NMOS gate dielectric layer in between depositing a PMOS hardmask layer over the PMOS gate electrode. The exemplary method further incldues depositing an NMOS hardmask layer over the NMOS gate electrode, forming a PMOS oxide liner over a portion of the PMOS gate electrode, forming an NMOS oxide liner over a portion of the NMOS gate electrode, forming a nitride layer over the PMOS oxide liner and over the NMOS oxide liner, and depositing photoresist on the semiconductor substrate in a pattern that covers the NMOS device. The exemplary method further includes etching the nitride layer from the PMOS device, wherein the etching nitride layer leaves a portion of the nitride layer on the PMOS oxide liner, etching semiconductor substrate to form a Si recess, and depositing SiGe into the Si recesses, wherein the SiGe and the nitride layer enclose the PMOS oxide liner. Additionally, depositing SiGe can further include depositing boron (B) doped SiGe. For example SiGe deposition can be done in-situ doped with boron resulting in boron levels greater than 10¹⁹/cm³ and as much as greater than 10²⁰/cm³ in the SiGe film.

The CMOS device in this invention as well as the processes of the invention can be carried out in equipment known in the art of atomic layer epitaxy (ALE), chemical vapor deposition (CVD) and atomic layer deposition (ALD). The apparatus brings the sources into contact with a heated substrate on which the silicon compound films are grown. The processes can operate at a range of pressures from about 1 mTorr to about 2,300 Torr, preferably between about 0.1 Torr and about 200 Torr. Hardware that can be used to deposit silicon-containing films includes the Epi Centura™ RP (reduced pressure) system, the DPS II™ silicon etch tool, and the Poly Gen™ system available from Applied Materials, Inc., located in Santa Clara, Calif. A suitable ALD apparatus is disclosed in U.S. Patent Application Publication No. 20030079686, assigned to Applied Materials, Inc., and entitled “Gas Delivery Apparatus and Methods for ALD”, which publication is incorporated herein by reference in entirety for the purpose of describing the apparatus. Other suitable apparatus include batch, high-temperature furnaces, as known in the art.

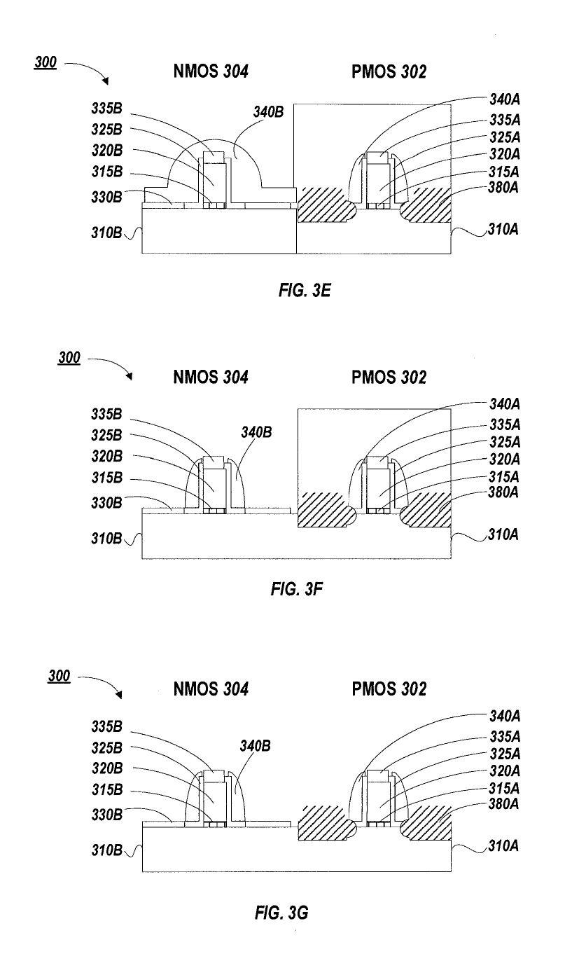

Exemplary embodiments of the present invention provides for an integration scheme, which is used to manufacture CMOS devices, that is not as susceptible to defects that arise during the SiGe epi deposition process because of over etching in previous processes. FIGS. 3A-3G illustrate one embodiment of an integration scheme, which is used to manufacture the SiGe source/drain in a CMOS device, that is not susceptible to process variations that cause over etching.

FIG. 3A illustrates a partially fabricated CMOS 300 having a partially fabricated PMOS device 302 and a partially fabricated NMOS device 304 positioned side-by-side next to each other. The PMOS device 302 has a PMOS substrate 310A, a PMOS gate dielectric layer 315A, a PMOS gate electrode 320A, a PMOS oxide layer 325A, a PMOS oxide stopping layer 330A, a PMOS hardmask 335A, and a PMOS spacer nitride layer 340A. Similarly the NMOS device 304 has an NMOS substrate 310B, an NMOS gate dielectric layer 315B, an NMOS gate electrode 320B, an NMOS oxide layer 325B, an NMOS oxide stopping layer 330B, an NMOS hardmask 335B, an NMOS spacer nitride layer 340B, and an NMOS photoresist layer 350. In FIG. 3A, both the PMOS device 302 and NMOS device 304 can be fabricated on the same substrate. Additionally, both the PMOS device 302 and the NMOS device 304 can both share the same spacer nitride layer. The oxide stopping layer 330 can be deposited directly onto the substrate and can be the same layer shared by both the PMOS device 302 and the NMOS device 304.

In one embodiment of the present invention, PMOS substrate 310A and NMOS substrate 310B can be silicon substrates. For example, PMOS substrate 310A can be an n-type substrate whereas NMOS substrate 310B can be a p-type substrate. In one embodiment of the present invention, NMOS transistors are formed in p-type substrates by diffusing n-type material into the substrate. PMOS transistors can be formed by diffusing a well of n-type material into the substrate so that p-type diffusion then defines the drain and source of the PMOS transistors. In this embodiment, both the NMOS and PMOS devices can be constructed on a p-type substrate.

PMOS gate dielectric layer 315A and NMOS gate dielectric layer 315B can include layers containing a silicon oxide, a silicon nitride, or a silicon oxynitride. These layers can be deposited to a thickness ranging between about 5 angstroms and about 100 angstroms. PMOS gate dielectric layer 315A can be formed on top of a region of a p-type substrate having a well of n-type material formed into the substrate so that p-type diffusion occurs. Similarly, NMOS gate dielectric layer 315B can be formed on top of a region of a p-type substrate that has been diffused by n-type material.

PMOS gate electrode 320A is formed on PMOS gate dielectric layer 315A by depositing polysilicon onto the PMOS gate dielectric layer 315A and patterning the polysilicon with photolithographic techniques. The deposited polysilicon layer forming the PMOS gate electrode 320A can have a thickness ranging from about 500 angstroms to about 3500 angstroms. Alternatively, the PMOS gate electrode 320A can comprise other conductive materials, such as metals. Similarly, NMOS gate electrode 320B is formed on NMOS gate dielectric layer 315B by depositing polysilicon onto the NMOS gate dielectric layer 315B and patterning the polysilicon with photolithographic techniques. The deposited polysilicon layer forming the NMOS gate electrode 320B can also have a thickness ranging from about 500 angstroms to about 3500 angstroms. Alternatively and as with the PMOS gate electrode 320A, the NMOS gate electrode 320B can also comprise other conductive materials, such as metals.

PMOS oxide layer 325A may be formed along laterally opposite sidewalls of the PMOS gate electrode 320A as well as on portions of substrate 310. The PMOS oxide layer 325A formed on portions of the substrate 310 are formed in between the PMOS gate electrode 320A and the PMOS oxide stopping layer 330A, which has been deposited on top of the substrate 310. The PMOS oxide layer 325A formed on the lateral opposite walls of the PMOS gate electrode 320A can form a plane that is substantially perpendicular to the PMOS oxide layer 325A formed on the substrate 310. The PMOS oxide layer 325A is thick enough to electrically isolate the PMOS gate electrode 320A from subsequently deposited materials and can have a thickness ranging from about 10 angstroms to about 100 angstroms. PMOS oxide layer 325A can also be substituted for other suitable insulating materials such as silicon oxide, silicon oxynitride, silicon nitride, or high k dielectric materials such as HfO₂, Al₂O₃ etc., which can be deposited using deposition processes such as physical vapor deposition, sputtering, ion-beam deposition, and chemical vapor deposition. Once these materials are deposited they can be further etched using wet etching, dry etching, plasma etching or other etching techniques to produce the structures shown in FIGS. 3A-3G.

NMOS oxide layer 325B may also be formed along laterally opposite sidewalls of the NMOS gate electrode 320B as well as on portions of substrate 310. The NMOS oxide layer 325B formed on portions of the substrate 310 are formed in between the NMOS gate electrode 320B and the NMOS oxide stopping layer 330B, which has been deposited on top of the substrate 310. The NMOS oxide layer 325B formed on the lateral opposite walls of the NMOS gate electrode 320B can form a plane that is substantially perpendicular to the NMOS oxide layer 325B formed on the substrate 310. The NMOS oxide layer 325B is thick enough to electrically isolate the NMOS gate electrode 320B from subsequently deposited materials and can have a thickness ranging from about 10 angstroms to about 100 angstroms. NMOS oxide layer 325B can also be substituted for other suitable insulating materials such as silicon oxide, silicon oxynitride, silicon nitride, or high k dielectric materials such as HfO₂, Al₂O₃ etc., which can be deposited using deposition processes such as physical vapor deposition, sputtering, ion-beam deposition, and chemical vapor deposition. Once these materials are deposited they can be further etched using wet etching, dry etching, plasma etching or other etching techniques to produce the structures shown in FIGS. 3A-3G.

The PMOS oxide stopping layer 330A and the PMOS oxide stopping layer 330B can be deposited directly on top of the substrate 310 using deposition techniques such as CVD, PVD, sputtering, Ion Beam Deposition, plating, high temperature oxide deposition, low temperature oxide deposition, etc.

PMOS hardmask 335A can be deposited directly on top of the PMOS gate electrode 320A or can be deposited on top of other materials that are deposited on top of the PMOS gate electrode 320A (e.g., there can be intermediate layers between the PMOS gate electrode 320A and the PMOS hardmask 335A). Similarly, the NMOS hardmask 335B can be deposited directly on top of the NMOS gate electrode 320B or can be deposited on top of other materials that are deposited on top of the NMOS gate electrode 320B (e.g., there can be intermediate layers between the NMOS gate electrode 320B and the NMOS hardmask 335B. Both the PMOS hardmask 335A and the NMOS hardmask 335B material may be any material used in hardmask application, including silicon oxide or silicon nitride. The hardmask material and may be deposited using deposition processes such as plasma enhanced chemical vapor deposition (PECVD) and low pressure chemical vapor deposition (LPCVD).

PMOS spacer nitride layer 340A and NMOS spacer nitride layer 340B can be deposited as one layer over the substrate having the PMOS hardmask 335A and NMOS hardmask 335B already deposited over the electrodes. Both the PMOS spacer nitride layer 340A and the NMOS spacer nitride layer 340B can be deposited directly over the hardmask layers or after other intermediate layers are deposited on top of the hardmask layers. PMOS spacer nitride layer 340A and NMOS spacer nitride layer 340B can also be deposited as one film at the same time using deposition techniques such as sputtering, chemical vapor deposition, physical vapor deposition etc.

NMOS photoresist layer 350 is deposited over the NMOS spacer nitride layer 340B and is used to protect the NMOS device 304 while the PMOS device 302 is processed. NMOS photoresist layer 350 is deposited over NMOS nitride layer 340B using photolithographic techniques.

FIG. 3B shows the partially fabricated CMOS 300 after the nitride spacer has been opened by etching processes. In FIG. 3B the partially fabricated NMOS device 304 remains the same after the etching process because it is protected by the photoresist. However, since the partially fabricated PMOS device 302 does not have photoresist, the PMOS spacer nitride layer 340A is etched off leaving a nitride layer covering the PMOS oxide layer 330A. The etching process removes the PMOS spacer nitride layer 340A so that the PMOS hardmask 335A is exposed on top but partially covered on the sides. Additionally, the PMOS spacer nitride layer 340A is etched so that the PMOS oxide stopping layer 330A is exposed.

FIG. 3C shows the partially fabricated CMOS 300 after the partially fabricated PMOS device 302 has been implanted and recesses for the source and drain have been etched into the substrate. In FIG. 3C the partially fabricated NMOS device 304 remains the same after the etching process because it is protected by the photoresist, as it was protected in FIG. 3B. FIG. 3C shows that the etching process has removed the PMOS oxide stopping layer 330A in the PMOS device 304 and further has removed a portion of the substrate leaving a recessed region in the substrate for depositing the source/drain of the PMOS device 302.

FIG. 3D shows the partially fabricated CMOS 300 after the photoresist covering the partially fabricated NMOS device 304 has been stripped away, the entire CMOS 300 device cleaned and the silicon-germanium (SiGe) 380A is deposited into the recesses of FIG. 3C. In an alternative embodiment, an additive can include boron doped SiGe is deposited is deposited instead of SiGe.

FIG. 3E shows the partially fabricated CMOS 300 the PMOS device 302 of FIG. 3D covered with photoresist and the NMOS device 304 left uncovered and ready to be processed. Therefore, after PMOS device 302 is processed as shown in FIG. 3A-3D, the NMOS device 304 is prepared for processing by first protecting the adjacent PMOS device 302.

FIG. 3F shows the partially fabricated CMOS 300 after the NMOS spacer nitride layer 340B has been opened by etching processes. In FIG. 3F the PMOS device 302 remains the same after this etching process because it is protected by the photoresist. However, since the partially fabricated NMOS device 304 does not have photoresist, the NMOS spacer nitride layer 340B is etched off leaving a nitride layer covering the NMOS oxide layer 330B. The etching process removes the NMOS spacer nitride layer 340B so that the NMOS hardmask 335B is exposed on top but partially covered on the sides. Additionally, the NMOS spacer nitride layer 340B is etched so that the NMOS oxide stopping layer 330B is exposed.

FIG. 3G shows the partially fabricated CMOS 300 after the NMOS device 304 has been implanted and the photoresist covering the PMOS device 302 has been stripped away, the entire CMOS 300 device cleaned.

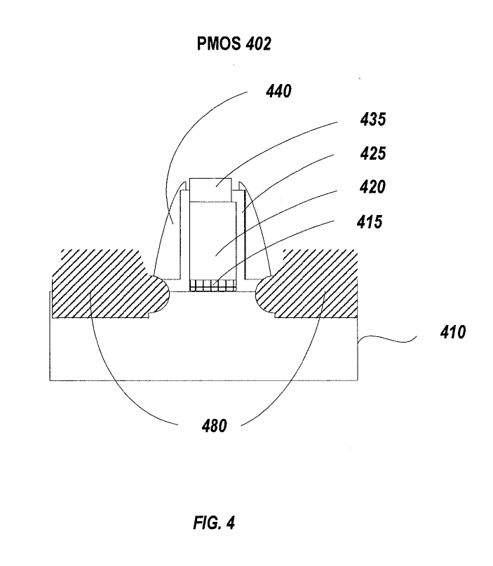

FIG. 4 illustrates a PMOS device that has been properly etched during the steps described above with reference to FIGS. 3A-3G and SiGe has grown only in the Si recess regions during the SiGe epitaxial deposition process, in accordance with one embodiment of the invention. The PMOS device 402 has a PMOS substrate 410, a PMOS gate dielectric layer 415, a PMOS gate electrode 420, a PMOS oxide layer 425, a PMOS hardmask 435, a PMOS spacer nitride layer 440, and a SiGe source/drain 480. In one embodiment, PMOS substrate 410 is made of a p-type silicon which has an n-well type material diffused into it. The gate dielectric layer 415 is made of silicon oxide and is deposited over the n-well formed in the p-type silicon substrate. The PMOS gate electrode 420 is formed over PMOS gate electrode layer 415 and is made of polysilicon. In one embodiment, the PMOS gate electrode is in direct contact with the PMOS dielectric layer 415. The PMOS oxide layer 425, which has a height ranging from 1000 Angstroms to 3000 Angstroms, is formed along laterally opposite sidewalls of the PMOS gate electrode 420 as well as on portions of substrate 410. The PMOS oxide layer 425, which is formed on the lateral opposite walls of the PMOS gate electrode 420, also forms a plane that is substantially perpendicular to the PMOS oxide layer 425 formed on the substrate 410. The PMOS oxide layer 425 is thick enough to electrically isolate the PMOS gate electrode 420 from subsequently deposited materials and can have a thickness ranging from about 10 angstroms to about 100 angstroms. The PMOS oxide layer 425 can also be substituted for other suitable insulating materials such as silicon oxide, silicon oxynitride, silicon nitride, or high k dielectric materials such as HfO₂, Al₂O₃ etc., which can be deposited using deposition processes such as physical vapor deposition, sputtering, ion-beam deposition, chemical vapor deposition. Once these materials are deposited they can be further etched using wet etching, dry etching, plasma etching or other etching techniques according to the techniques described with reference to FIGS. 3A-3G, above.

PMOS hardmask 435 is made of any material used in hardmask applications such as silicon oxide or silicon nitride. PMOS hardmask 435 is deposited directly on top of the PMOS gate electrode 420 using deposition processes such as plasma enhanced chemical vapor deposition (PECVD) and low pressure chemical vapor deposition (LPCVD). In one embodiment, PMOS hardmask 435 is deposited directly on top of the PMOS gate electrode 420 whereas in other embodiments other materials are deposited between the PMOS gate electrode 420 and the PMOS hardmask 435.

PMOS nitride layer 440 is the nitride layer that is left over after the etch steps used to create the Si recesses have been completed. PMOS nitride layer 440 substantially covers PMOS oxide layer 425 by extending both along the lengths of the PMOS oxide layer 425 that is formed along the laterally opposed walls of the PMOS gate electrode 420 and along the PMOS oxide layer 425 deposited on the substrate 410. Moreover the PMOS nitride layer 440 covers the PMOS gate electrode 420 so that the SiGe is not deposited on the polysilicon of the electrode. The PMOS nitride layer 440 is narrower on top near the PMOS hardmask 435 than it is below near the substrate 410. PMOS nitride layer 440 is made of nitride containing material such as Bis-TertiaryButylAmino-Silane (BTBAS).

SiGe source/drain 480 regions have been etched into substrate 410 and then filled with SiGe using selective epitaxial deposition techniques. The SiGe deposited into the source/drain 480 extends above the surface of substrate 410 sufficiently enough to enclose the PMOS oxide layer 425. In one embodiment the SiGe makes direct contact with the PMOS nitride layer 440 enclosing the PMOS oxide layer 425 and therefore shielding the PMOS oxide layer 425 from subsequent process steps such as etching. In other embodiments, PMOS oxide layer 425 is enclosed and shielded from subsequent processing steps but the SiGe and the PMOS nitride layer 440 are not in direct contact. This can occur if an intermediate material is used between the PMOS nitride layer 440 and the PMOS oxide layer 425. In an alternative embodiment SiGe doped with boron can also be used.

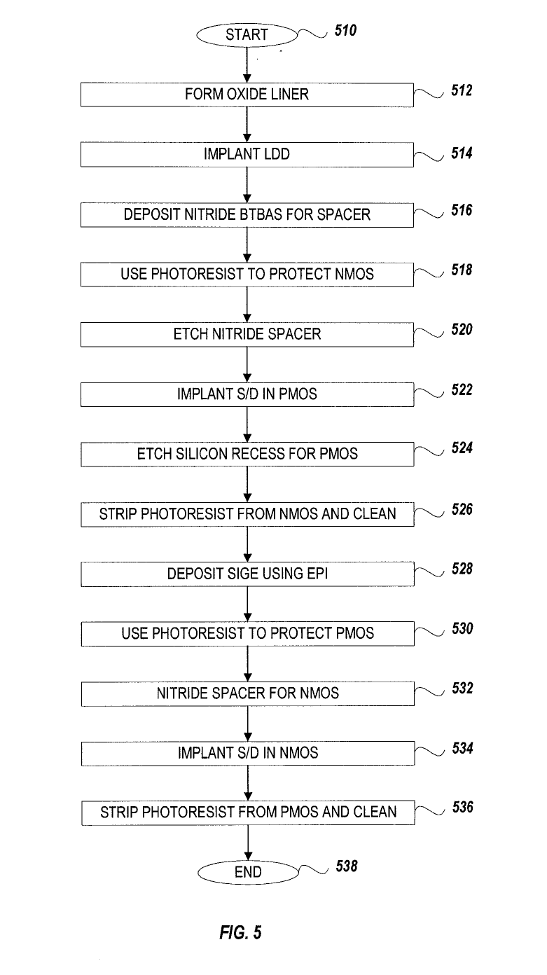

FIG. 5 is a flow chart showing an exemplary method used to manufacture a CMOS using silicon-germanium as a source/drain material without using a cap layer, in accordance with one embodiment of the invention. The CMOS being manufactured includes a PMOS device and NMOS device also being manufactured, which are positioned side by side. The process starts in step 510 when a partially fabricated PMOS device is introduced. The partially fabricated PMOS has already undergone several processes including the deposition of polysilicon to grow the gate electrode. In step 512, the PMOS oxide liner is formed on the gate electrode by depositing a material such as silicon oxide, silicon oxynitride, silicon nitride, or high k dielectric materials such as HfO₂, Al₂O₃ etc. using deposition processes such as physical vapor deposition, sputtering, ion-beam deposition or chemical vapor deposition. Before the PMOS oxide liner is deposited onto the PMOS gate electrode, the PMOS gate electrode can optionally be etched so that it is cleaner. The etching step becomes more important if the PMOS gate electrode has been exposed to ambient conditions before step 512 such as during transferring between process tools.

Next in step 514, the LDD implant process is done on the structure having the gate electrode having the PMOS oxide liner. In step 516, a PMOS nitride layer is deposited onto the entire surface of the substrate by exposing the substrate along with the oxide layer to a Bis-TertiaryButylAmino-Silane (BTBAS) material. In step 518, a photoresist layer is deposited over the NMOS devices of the CMOS. The photoresist is first spin coated onto the entire wafer and then photolithography is used to pattern the photoresist so that the PMOS devices are not covered with photoresist but the NMOS devices are covered with photoresist. Photolithography techniques include using a mask to create the desired photoresist pattern on the wafer and as the devices become smaller it becomes more difficult to align the masks with the wafer. The alignment process is done using steppers to carefully position the masks over the wafer.

Next in step 520, the nitride layer is etched so that the nitride spacer is opened. This etching step only etches the nitride layer from the partially fabricated PMOS device and not the partially fabricated NMOS device because the NMOS device is protected with photoresist whereas the PMOS device is not protected. The etching process removes the PMOS spacer nitride layer so that the PMOS hardmask is exposed on top but partially covered on the sides. This etching process can be performed using fluorine based gases having chemistries such as CF₄, CHF₃, CH₂F₂, C₄F₈, C₂F₆, etc. The process gas pressure can range from 2 to 80 mTorr and the plasma power can range from 200 to 2000 Watts. The substrate bias power can range from 20 to 200 Watts while the substrate temperature can range from 0 to 80 Celsius. In one embodiment this etching process is done using CF₄/CHF₃ process gas at about 4 mTorr in a 500 Watt plasma (approximately), with the substrate biased with 80 Watts (approximately) of power and held at a temperature of about 60 Celsius.

Next in step 522, the areas designated for the source/drain of the PMOS are implanted with impurities. Some examples of the impurities used include B and BF₃. Immediately after the source/drain regions have been implanted with impurities, the silicon recesses are etched into the substrate in step 524. In one embodiment this etching process is done using fluorine based process gases such as mixtures of NF₃, Cl₂, O₂, and Ar. The process gas pressure can range from 4 to 50 mTorr and the plasma power can range from 200 to 1000 Watts.

Next in step 526 the photoresist is stripped from the CMOS and the CMOS is cleaned, so that the NMOS device is no longer covered with photoresist. This is done to prepare the substrate for depositing SiGe in the source/drain regions. In step 528, the SiGe is deposited into the source/drain region using epitaxial deposition such as Chemical Vapor Deposition (CVD), it can be at reduced pressure (RP). In one embodiment the epitaxial deposition process is done using dichlorosilane (DCS), silane, or disilane as the silicon source, germane, GeH₄ as the germanium source, and HCl for selective epi deposition. The process gas pressure can range from 1 to 80 Torr while the substrate temperature ranges from 600 to 800 Celsius during deposition step. In one embodiment the carrier gas is H₂ and the process gas pressure is 10 Torr and the substrate temperature is 650 to 750 Celsius. In another embodiment, depositing SiGe can further include depositing boron (B) doped SiGe. For example, SiGe deposition can be done in-situ doped with boron resulting in boron levels greater than 10¹⁹/cm³ and as much as greater than 10²⁰/cm³ in the SiGe film.

Once the SiGe source drains have been deposited, the wafer is prepared so that the NMOS region can be processed instead of the PMOS regions. These next steps are very similar to the steps used to process the PMOS device. In step 530, the PMOS devices are protected by covering them with photoresist in the same way the NMOS devices were protected with photoresist in step 518. As in step 518, the entire wafer is first covered with photoresist material that is spin coated onto the wafer and then photolithographic techniques are used to pattern photoresist on the wafer so that only the PMOS portions of the wafer remain covered with photoresist. Next in step 532, the nitride spacer is etched open so that only the nitride layer from the partially fabricated NMOS device is etched. The etching process removes the NMOS spacer nitride layer so that the NMOS hardmask is exposed on top but partially covered on the sides. This etching process can be performed using fluorine based gases having chemistries such as CF₄, CHF₃, CH₂F₂, C₄F₈, C₂F₆, etc. The process gas pressure can range from 2 to 80 mTorr and the plasma power can range from 200 to 2000 Watts. The substrate bias power can range from 20 to 200 Watts while the substrate temperature can range from 0 to 80 Celsius. In one embodiment this etching process is done using CF₄/CHF₃ process gas at about 4 mTorr in a 500 Watt plasma (approximately), with the substrate biased with 80 Watts (approximately) of power and held at a temperature of about 60 Celsius.

Next in step 534, the areas designated for the source/drain on the NMOS are implanted with impurities. Immediately after the source/drain regions have been implanted with impurities, the NMOS photoresist is stripped away from the wafer and the wafer is clean in step 536. The process ends in step 538 by transporting the wafer to the next process which can include further depositions and etchings.

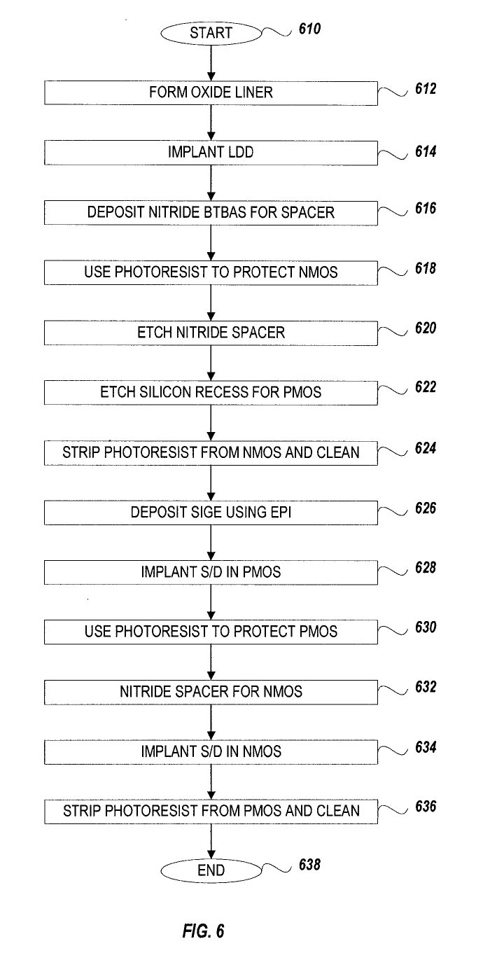

FIG. 6 is a flow chart showing an alternative set of steps used to manufacture a CMOS using silicon-germanium as a source/drain material without using a cap layer, in accordance with another embodiment of the invention. As described above with reference to FIG. 5, the CMOS being manufactured includes a PMOS device and NMOS device also being manufactured, which are positioned side by side. The process starts in step 610 when a partially fabricated PMOS device is introduced. The partially fabricated PMOS has already undergone several processes including the deposition of polysilicon to grow the gate electrode. In step 612, the PMOS oxide liner is formed on the gate electrode by depositing a material such as silicon oxide, silicon oxynitride, silicon nitride, or high k dielectric materials such as HfO₂, Al₂O₃ etc. using deposition processes such as physical vapor deposition, sputtering, ion-beam deposition or chemical vapor deposition. Before the PMOS oxide liner is deposited onto the PMOS gate electrode, the PMOS gate electrode can optionally be etched so that it is cleaner. The etching step becomes more important if the PMOS gate electrode has been exposed to ambient conditions before step 612 such as during transferring between process tools.

Next in step 614, the LDD implant process is done on the structure having the gate electrode having the PMOS oxide liner. In step 616, a PMOS nitride layer is deposited onto the entire surface of the substrate by exposing the substrate along with the oxide layer to a Bis-TertiaryButylAmino-Silane (BTBAS) material. In step 618, a photoresist layer is deposited over the NMOS devices of the CMOS. The photoresist is first spin coated onto the entire wafer and then photolithography is used to pattern the photoresist so that the PMOS devices are not covered with photoresist but the NMOS devices are covered with photoresist. Photolithography techniques include using a mask to create the desired photoresist pattern on the wafer and as the devices become smaller it becomes more difficult to align the masks with the wafer. The alignment process is done using steppers to carefully position the masks over the wafer.

Next in step 620 the nitride layer is etched so that the nitride spacer is opened. This etching step only etches the nitride layer from the partially fabricated PMOS device and not the partially fabricated NMOS device because the NMOS device is protected with photoresist whereas the PMOS device is not protected. The etching process removes the PMOS spacer nitride layer so that the PMOS hardmask is exposed on top but partially covered on the sides. This etching process can be performed using fluorine based gases having chemistries such as CF₄, CHF₃, CH₂F₂, C₄F₈, C₂F₆, etc. The process gas pressure can range from 2 to 80 mTorr and the plasma power can range from 200 to 2000 Watts. The substrate bias power can range from 20 to 200 Watts while the substrate temperature can range from 0 to 80 Celsius. In one embodiment this etching process is done using CF₄/CHF₃ process gas at about 4 mTorr in a 500 Watt plasma (approximately), with the substrate biased with 80 Watts (approximately) of power and held at a temperature of about 60 Celsius. After the PMOS nitride spacer layer is etched, the silicon recesses are etched into the substrate in step 622. In one embodiment the silicon recess etching process 622 is done using fluorine based process gases such as mixtures of NF₃, Cl₂, O₂, and Ar. The process gas pressure can range from 4 to 50 mTorr and the plasma power can range from 200 to 1000 Watts.

Next in step 624 the photoresist is stripped from the CMOS and the CMOS is cleaned, so that the NMOS device is no longer covered with photoresist. This is done to prepare the substrate for depositing SiGe in the source/drain regions. In step 626, the SiGe is deposited into the source/drain region using epitaxial deposition such as Chemical Vapor Deposition (CVD), it can be at reduced pressure (RP). In one embodiment the epitaxial deposition process is done using dichlorosilane (DCS), silane, or disilane as the silicon source, germane, GeH4 as the germanium source, and HCl for selective epi deposition. The process gas pressure can range from 1 to 80 Torr while the substrate temperature ranges from 600 to 800 Celsius during deposition step. In one embodiment the carrier gas is H₂ and the process gas pressure is 10 Torr and the substrate temperature is 650 to 750 Celsius. In another embodiment, depositing SiGe can further include depositing boron (B) doped SiGe. For example, SiGe deposition can be done in-situ doped with boron resulting in boron levels greater than 10¹⁹/cm³ and as much as greater than 10²⁰/cm³ in the SiGe film. Next in step 628, the areas designated for the source/drain of the PMOS are implanted with impurities. Some examples of the impurities used include B and BF₃. Immediately after the source/drain regions have been implanted with impurities,

Once the SiGe source drains have been deposited, the wafer is prepared so that the NMOS region can be processed instead of the PMOS regions. These next steps are very similar to the steps used to process the PMOS device. In step 630, the PMOS devices are protected by covering them with photoresist in the same way the NMOS devices were protected with photoresist in step 618. As in step 618, the entire wafer is first covered with photoresist material that is spin coated onto the wafer and then photolithographic techniques are used to pattern photoresist on the wafer so that only the PMOS portions of the wafer remain covered with photoresist. Next in step 632, the nitride spacer is etched open so that only the nitride layer from the partially fabricated NMOS device is etched. The etching process removes the NMOS spacer nitride layer so that the NMOS hardmask is exposed on top but partially covered on the sides. This etching process can be performed using fluorine based gases having chemistries such as CF₄, CHF₃, CH₂F₂, C₄F₈, C₂F₆, etc. The process gas pressure can range from 2 to 80 mTorr and the plasma power can range from 200 to 2000 Watts. The substrate bias power can range from 20 to 200 Watts while the substrate temperature can range from 0 to 80 Celsius. In one embodiment this etching process is done using CF₄/CHF₃ process gas at about 4 mTorr in a 500 Watt plasma (approximately), with the substrate biased with 80 Watts (approximately) of power and held at a temperature of about 60 Celsius.

Next in step 634, the areas designated for the source/drain on the NMOS are implanted with impurities. Immediately after the source/drain regions have been implanted with impurities, the NMOS photoresist is stripped away from the wafer and the wafer is clean in step 636. The process ends in step 638 by transporting the wafer to the next process which can include further depositions and etchings.

It will also be recognized by those skilled in the art that, while the invention has been described above in terms of preferred embodiments, it is not limited thereto. Various features and aspects of the above-described invention may be used individually or jointly. Further, although the invention has been described in the context of its implementation in a particular environment and for particular applications, those skilled in the art will recognize that its usefulness is not limited thereto and that the present invention can be utilized in any number of environments and implementations.

What is claimed is:

1. A method for fabricating a semiconductor device with adjacent PMOS and NMOS devices on a substrate comprising:
forming a PMOS gate electrode with a PMOS hardmask on a semiconductor substrate with a PMOS gate dielectric layer in between;
forming an NMOS gate electrode with an NMOS hardmask on a semiconductor substrate with an NMOS gate dielectric layer in between forming an oxide liner over a portion of said PMOS gate electrode and over a portion of said NMOS gate electrode;
forming a lightly doped drain (LDD) and N-Halo implant regions in PMOS and NMOS;
depositing a nitride layer over said oxide liner;
depositing photoresist on said semiconductor substrate in a pattern that covers said NMOS device;
etching said nitride layer from said PMOS device, wherein said etching nitride layer leaves a portion of said nitride layer on said oxide liner;
etching semiconductor substrate to form a Si recess in a source region and a drain region of PMOS; and
depositing SiGe into said Si recesses, wherein said SiGe and said nitride layer enclose said oxide liner.

2. The method of claim 1 wherein said depositing SiGe includes depositing boron (B) doped SiGe.

3. The method of claim 1 further comprising implanting said source and drain region with highly doped drain (HDD) conditions for said PMOS.

4. The method of claim 3 further comprising the step of dopant activation anneal.

5. The method of claim 4 wherein said step of dopant activation anneal is performed immediately after HDD implant and before recess etch.

6. The method of claim 4 wherein said step of dopant activation anneal is performed after SiGe deposition.

7. The method of claim 3 wherein said HDD implant is performed after SiGe deposition.

8. The method of claim 1 further comprising stripping said photoresist from said NMOS.

9. The method of claim 8 further comprising cleaning said surface of said semiconductor substrate.

10. The method of claim 1 wherein said step of forming a nitride space layer includes exposing said semiconductor substrate to a process gas comprising Bis-TertiaryButylAmino-Silane (BTBAS).

11. The method of claim 1 wherein said SiGe is deposited into said Si recesses using epitaxial deposition.

12. The method of claim 1 wherein said oxide liner is formed along laterally opposite sidewalls of the PMOS gate electrode.

13. The method of claim 1 wherein said oxide liner is formed along laterally opposite sidewalls of the NMOS gate electrode.

14. The method of claim 1 wherein said oxide liner is formed along laterally opposite sidewalls of the PMOS gate electrode and extends above said PMOS gate electrode and contacts said PMOS hardmask.

15. The method of claim 14 wherein said step of etching semiconductor substrate to form a Si recess reduces the height of said oxide liner so that the final height of said oxide liner extends above the height of said PMOS gate electrode.

16. The method of claim 1 wherein said PMOS hardmask layer is deposited directly over said PMOS gate electrode.

17. The method of claim 1 wherein said NMOS hardmask layer is deposited directly over said NMOS gate electrode.

18. The method of claim 1 wherein said step of etching semiconductor substrate to form a Si recess reduces the height of said oxide liner so that the final height of said oxide liner extends above the height of said PMOS gate electrode.

19. The method of claim 1 further comprising:
stripping said photoresist from said NMOS;
depositing photoresist on said semiconductor substrate in a pattern that covers said PMOS device after said SiGe has been deposited into said Si recess;
etching said nitride layer from said NMOS device, wherein said etching nitride layer leaves a portion of said nitride layer on said NMOS oxide liner;

20. The method of claim 1 further comprising:
stripping said photoresist from said NMOS;
depositing a oxide liner layer on said PMOS device
etching said oxide liner layer and said nitride layer from said NMOS device, wherein said etching nitride layer leaves a portion of said nitride layer on said NMOS oxide liner;

21. The method of claim 20 further comprising:
etching said semiconductor substrate to form an NMOS Si recess; and
selectively depositing Si:C into said NMOS Si recesses, wherein said Si:C and said nitride layer enclose said NMOS oxide liner.

22. The method of claim 20 further comprising:
selectively depositing Si:C into an NMOS un-recessed source and drain areas, wherein said Si:C and said nitride layer enclose said NMOS oxide liner.

23. The method of claim 19 wherein said NMOS oxide liner is formed along laterally opposite sidewalls of the NMOS gate electrode and extends above said NMOS gate electrode and contacts said NMOS hardmask.

24. The method of claim 23 wherein said step of etching semiconductor substrate to form a Si recess reduces the height of said NMOS oxide liner less than the amount said NMOS oxide liner extends above said NMOS gate electrode.

25. The method of claim 19 further comprising stripping said photoresist from said PMOS.

26. A method for fabricating a semiconductor device with adjacent PMOS and NMOS devices on a substrate comprising:
forming a nitride layer over a partially fabricated PMOS device and a partially fabricated NMOS device;
depositing photoresist on said semiconductor substrate in a pattern that covers said partially fabricated NMOS device;
etching through said nitride layer to form Si recesses in said substrate, wherein a portion of said nitride layer remains on said partially fabricated PMOS device;
depositing SiGe into said Si recesses, wherein said SiGe and said nitride layer enclose a PMOS gate electrode located in said partially fabricated PMOS device.

27. The method of claim 26 wherein said step of forming a nitride space layer includes exposing said semiconductor substrate to a process gas comprising Bis-TertiaryButylAmino-Silane (BTBAS).

28. The method of claim 26 further comprising:
stripping said photoresist from said partially fabricated NMOS device;
depositing photoresist on said semiconductor substrate in a pattern that covers said PMOS device after said SiGe has been deposited into said Si recess;
etching through said nitride layer to form Si recesses in said substrate, wherein a portion of said nitride layer remains on said partially fabricated NMOS device;
depositing SiC into said Si recesses, wherein said SiC and said nitride layer enclose a NMOS gate electrode located in said partially fabricated NMOS device.
